(19) United States
(12) Patent Application Publication
(10) Pub. No.: US 2024/0396222 A1
(43) Pub. Date: Nov. 28, 2024

(54) ELECTROMAGNETIC WAVE REFLECTION DEVICE, ELECTROMAGNETIC WAVE REFLECTION FENCE, INSTALLATION METHOD OF ELECTROMAGNETIC WAVE REFLECTION DEVICE, AND INSTALLATION METHOD OF ELECTROMAGNETIC WAVE REFLECTION FENCE

(71) Applicant: AGC Inc., Tokyo (JP)

(72) Inventor: Kumiko KAMBARA, Tokyo (JP)

(73) Assignee: AGC Inc., Tokyo (JP)

(21) Appl. No.: 18/791,239

(22) Filed: Jul. 31, 2024

Related U.S. Application Data
(63) Continuation of application No. PCT/JP2023/002798, filed on Jan. 30, 2023.

(30) Foreign Application Priority Data
Feb. 7, 2022 (JP) 2022-017518

(51) Int. Cl. H01Q 15/00

(52) U.S. Cl. CPC H01Q 15/0013

(57) ABSTRACT

An electromagnetic wave reflection device includes a reflection panel configured to reflect radio waves of a desired band selected from a frequency band of 1 GHz to 170 GHz; a frame configured to hold the reflection panel; a leg configured to support the frame; and a height adjustment mechanism configured to adjust a height of the reflection panel. The height adjustment mechanism is provided on at least one of the frame or the leg.

### CROSS-REFERENCE TO RELATED APPLICATION

This application is a continuation application of International Application No. PCT/JP2023/002798 filed on Jan. 30, 2023, and designated the U.S., which is based upon and claims priority to Japanese Patent Application No. 2022-017518, filed on Feb. 7, 2022, the entire contents of which are incorporated herein by reference.

### BACKGROUND

### 1. Field of the Invention

The present disclosure relates to an electromagnetic wave reflection device, an electromagnetic wave reflection fence, an installation method of the electromagnetic wave reflection device, and an installation method of the electromagnetic wave reflection fence.

### 2. Description of the Related Art

Automation of manufacturing processes and office tasks, and introduction of artificial intelligence (AI) control and management have led to introduction of indoor base stations in factories, plants, offices, and commercial facilities. The 5G mobile communication standard offers a frequency band below 6 GHZ, called “sub-6”, and a 28 GHz band that falls into a millimeter wave band. A next generation of the 6G mobile communication standard is expected to expand to a sub-terahertz band. By using such a high frequency band, a communication bandwidth can be greatly expanded, and a large amount of data communication can be performed with less delay.

A configuration in which electromagnetic wave reflection devices are arranged along at least a part of a process line has been proposed (for example, see International Publication No. WO2021/199504).

### SUMMARY

Radio waves in the millimeter wave band and the sub-terahertz band have high straightness due to their high frequency, a short propagation distance, and a great propagation loss. Indoor facilities such as factories, plants, and commercial facilities include various obstacles such as equipment and structures, making it difficult to maintain high communication quality. Although electromagnetic wave reflection devices can improve the radio wave propagation environment, a floor is not always horizontal or flat in some factories and plants. Even if the floor of the factory or plant is flat at the time of construction, the paint gradually comes off over the years due to the type and thickness of the coating film, a degree of base treatment, and influence of hot water, etc. Even when partial repairs are made, there are many places with poor flatness.

When electromagnetic wave reflection devices are to be installed in factories, etc., it is desirable that equipment engineers and contractors can easily assemble and install the electromagnetic wave reflection devices depending on the layout of the site. When the electromagnetic wave reflection devices also function as safety fences, it is desirable that height positions of electromagnetic wave reflection surfaces are the same from the viewpoint of at least one of electromagnetic wave reflection performance or safety. The present disclosure provides an electromagnetic wave reflection device that can be easily installed even in a place where the flatness of the installation surface is poor, while maintaining electromagnetic wave reflection performance.

In one embodiment, the electromagnetic wave reflection device includes a reflection panel configured to reflect radio waves of a desired band selected from the frequency band of 1 GHz to 170 GHz; a frame configured to hold the reflection panel; a leg configured to support the frame; and a height adjustment mechanism configured to adjust the height of the reflection panel. The height adjustment mechanism is provided on at least one of the frame or the leg.

### BRIEF DESCRIPTION OF DRAWINGS

FIG. 1 is a diagram illustrating an issue which may occur when flatness of an installation surface is poor;

FIG. 2 is a schematic diagram illustrating an electromagnetic wave reflection fence made by connecting a plurality of electromagnetic wave reflection devices;

FIG. 3 is a horizontal sectional view taken along line III-III of FIG. 2;

FIG. 4 is a schematic diagram illustrating an electromagnetic wave reflection device of a first embodiment;

FIG. 5 is a diagram illustrating an example of an adjuster used in a height adjustment mechanism;

FIG. 6 is a diagram illustrating another example of the adjuster used in the height adjustment mechanism;

FIG. 7A is a view illustrating cross section A taken at one height position of a frame;

FIG. 7B is a view illustrating cross section B taken at another height position of the frame;

FIG. 8A is a view illustrating cross section A taken at one height position of a frame in a modified example;

FIG. 8B is a view illustrating cross section B taken at another height position of a frame in the modified example;

FIG. 9A is a view illustrating cross section A of a frame of another modified example;

FIG. 9B is a view illustrating cross section B of the frame in the modified example;

FIG. 10 is a schematic diagram illustrating an electromagnetic wave reflection fence after assembly;

FIG. 11 is a schematic diagram illustrating an electromagnetic wave reflection device of a second embodiment;

FIG. 12 is a view illustrating cross section C of FIG. 10;

FIG. 13 is a schematic diagram illustrating an electromagnetic wave reflection fence of the second embodiment;

FIG. 14 is a schematic diagram illustrating an electromagnetic wave reflection device of a third embodiment;

FIG. 15 is a schematic diagram illustrating a height adjustment mechanism of FIG. 14;

FIG. 16 is a schematic diagram illustrating a process line to which an electromagnetic wave reflection fence is applied;

FIG. 17 is a table that summarizes specifications of a process line;

FIG. 18A is a diagram illustrating a model of a process line using electromagnetic wave reflection fences of a constant height according to an example;

FIG. 18B is a diagram illustrating a model of a process line using electromagnetic wave reflection fences with different heights according to a comparative example;

FIG. 19A is a diagram illustrating a model of the electromagnetic wave reflection device used in the comparative example;

FIG. 19B is a diagram illustrating a model of the electromagnetic wave reflection device of another height used in the comparative example;

FIG. 20 is a diagram illustrating a result of an electromagnetic field simulation of the process line that uses the electromagnetic wave reflection fence according to the example; and

FIG. 21 is a diagram illustrating a result of the electromagnetic field simulation of the process line that uses the electromagnetic wave reflection fence according to the comparative example.

### DESCRIPTION OF THE EMBODIMENTS

Provided is an electromagnetic wave reflection device which can be easily installed while maintaining electromagnetic wave reflecting performance even in a place where flatness of an installation surface is poor.

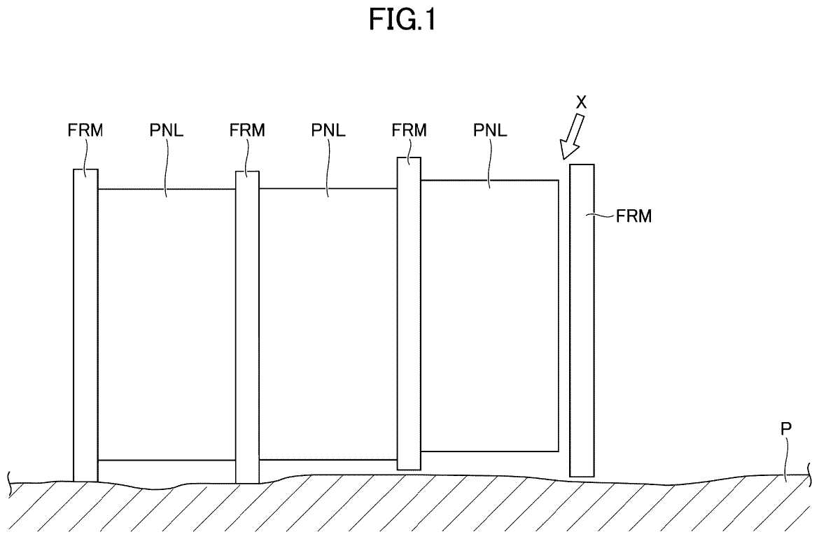

FIG. 1 is a diagram illustrating more specifically the issue that may occur when the flatness of an installation surface of the electromagnetic wave reflection device is poor. A case in which a plurality of reflection panel PNLs, reflecting electromagnetic waves in a predetermined frequency band are connected by frame FRMs, and used as an electromagnetic wave reflection fence is considered. When the reflection panel PNL of a same standard is installed in a place with poor flatness, a height position in which the reflection panel PNL is held can vary depending on an installation position of the frame FRM holding the reflection panel PNL. When the number of reflection panels is one or two, it may be possible to install the reflection panel PNL by forcibly fitting it into the frame FRM in a state where the height of the installation surface P varies. However, when a large number of reflection panel PNLs are connected, not only the height positions of the reflection panel PNLs become uneven, but also depending on an inclination of the installation surface P, some of the reflection panel PNLs may be held at different angles with respect to the frame FRM, and it may become difficult to maintain a uniform reflection potential between adjacent reflection panel PNLs.

When a height deviation of the reflection panel PNLs is accumulated, it becomes difficult to fit the reflection panel PNL into the frame FRM itself, as indicated by an arrow X. Such issues can occur not only in a factory or plant, but also when an electromagnetic wave reflection fence is installed outdoors. Therefore, in embodiments, an electromagnetic wave reflection device and an electromagnetic wave reflection fence that can be easily assembled and installed while maintaining electromagnetic wave reflecting performance even in a place where the flatness of the installation surface P is poor, are provided.

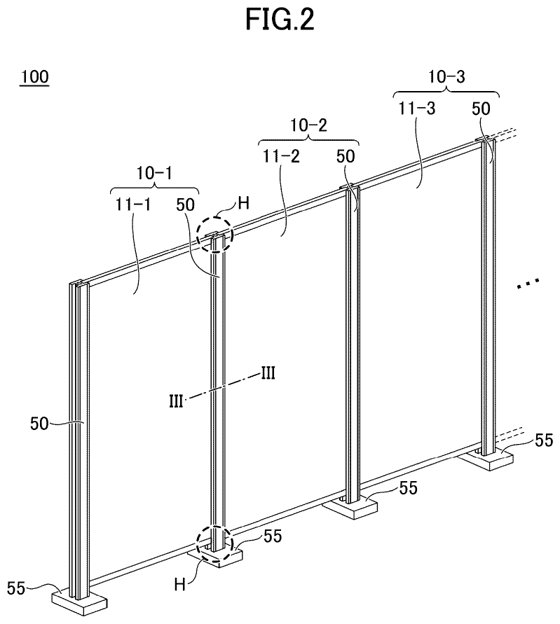

FIG. 2 is a schematic diagram illustrating an electromagnetic wave reflection fence 100 made by connecting electromagnetic wave reflection devices 10-1, 10-2, and 10-3. In the figure, the three electromagnetic wave reflection devices 10-1, 10-2, and 10-3 (hereinafter, collectively referred to as “electromagnetic wave reflection devices 10” as required) are connected to form the electromagnetic wave reflection fence 100, but the number of electromagnetic wave reflection devices 10 to be connected is not particularly limited.

The electromagnetic wave reflection devices 10-1, 10-2, and 10-3 include reflection panels 11-1, 11-2, and 11-3 (hereinafter, collectively referred to as “reflection panels 11” as required), respectively. Each of the reflection panels 11 reflects electromagnetic waves having frequencies ranging from 1 GHz to 170 GHz, preferably from 1 GHz to 100 GHz, and more preferably from 1 GHZ to 80 GHz. As will be described in the following, each reflection panel 11 includes as a reflection film a conductive film designed in accordance with a desired reflection mode, frequency band, and the like. The conductive film may be formed of a periodic pattern, a mesh pattern, a geometric pattern, a transparent film, and the like. As an example, a density of the mesh constituting the conductive film and a period of the repeating patterns are designed to reflect electromagnetic waves of 28 GHz±4 GHZ.

Each of the reflection panels 11-1, 11-2, and 11-3 may include a specular reflection surface having the same angle of incidence and emission of the electromagnetic waves, or may be a non-specular reflection surface having different angles of incidence and reflection. The non-specular reflection surface includes a diffusion surface, a scattering surface, and a metasurface which is an artificial reflective surface designed to reflect radio waves in a desired direction.

Side ends along a height direction of each reflection panel 11 are each held by a frame 50 and installed on an installation surface P (see FIG. 1) by a leg 55. In each of the electromagnetic wave reflection devices 10-1, 10-2, and 10-3, at least one of the frame 50 or the leg 55 is provided with a height adjustment mechanism H configured to adjust the height position of the corresponding reflection panel 11. A specific configuration of the height adjustment mechanism H will be described in the following.

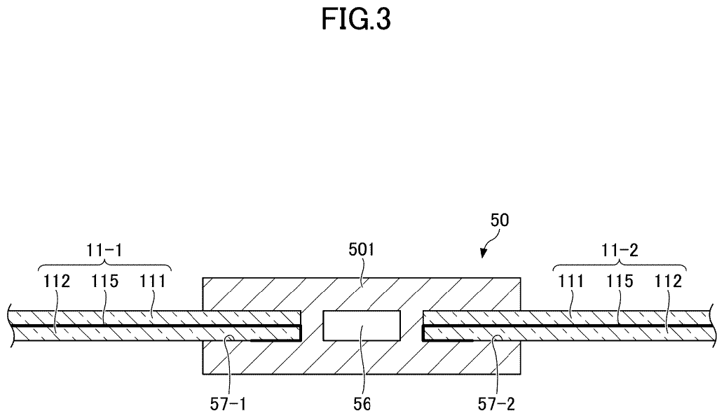

FIG. 3 is a horizontal sectional view taken along line III-III of FIG. 2. A horizontal cross section along the line III-III is a view, viewed from above, of the frame 50 and the reflection panels 11-1 and 11-2 held by the frame 50, cut in a plane horizontal to the installation surface. The frame 50 includes a body 501 made of a conductive material and slits 57-1 and 57-2 formed on two opposing sides of the body 501. The slit 57-1 holds one side end of the reflection panel 11-1 and the slit 57-2 holds one side end of the reflection panel 11-2.

The reflection panels 11-1 and 11-2 include, for example, a conductive film 115 and dielectric plates 111 and 112 sandwiching the conductive film 115. The body 501 of the frame 50 electrically connects the reflection panels 11-1 and 11-2 so that a reflection potential generated in the conductive film 115 is continuous or nearly uniform between the reflection panels 11-1 and 11-2 when an electromagnetic wave is incident on the electromagnetic wave reflection device 10. The body 501 of the frame 50 may be provided with a hollow 56 so long as the reflection potential is maintained nearly uniform between the reflection panels 11-1 and 11-2. The term “nearly uniform” is intended not to require that the two adjacent reflection panels be at exactly the same potential level, but to allow tolerable potential variations due to manufacturing differences, etc.

The hollow 56 does not communicate with either of the slits 57-1 or 57-2 and does not interfere with electrical connection between the frame 50 and the reflection panels 11-1 and 11-2. By providing the hollow 56 in the frame 50, the frame 50 can be reduced in weight.

In the example of FIG. 3, the conductive film 115 extends from a side end in each of the reflection panels 11-1 and 11-2 to a surface side of the dielectric plate 111 or 112 to ensure a contact area with the body 501 of the frame 50, but is not limited to this example. When the reflection potential continues to be substantially uniform or uninterrupted from the adjacent reflection panel 11, the conductive film 115 need not be pulled out to the surface side. Instead of sandwiching the conductive film 115 between two dielectrics, either of the dielectric plate 111 or 112 may be used to form the conductive film 115 on one surface of the dielectric plate. In this case, a ground film may be formed on the other surface of the dielectric plate.

In embodiments, the height adjustment mechanism H (see FIG. 1) is provided in the electromagnetic wave reflection device 10 to adjust the height position of the reflection panel 11. By making the height position of the reflection panel 11 adjustable, the electromagnetic wave reflection device 10 can be assembled and installed simply and appropriately according to conditions of the installation surface. When a plurality of electromagnetic wave reflection devices 10 are connected to form an electromagnetic wave reflection fence, not only the height positions of the plurality of reflection panels can be aligned to maintain the reflection characteristics well, but also is advantageous from a viewpoint of appearance and safety. In the following embodiments, there is a case where the same components are given the same reference numerals and duplicate descriptions are avoided.

### First Embodiment

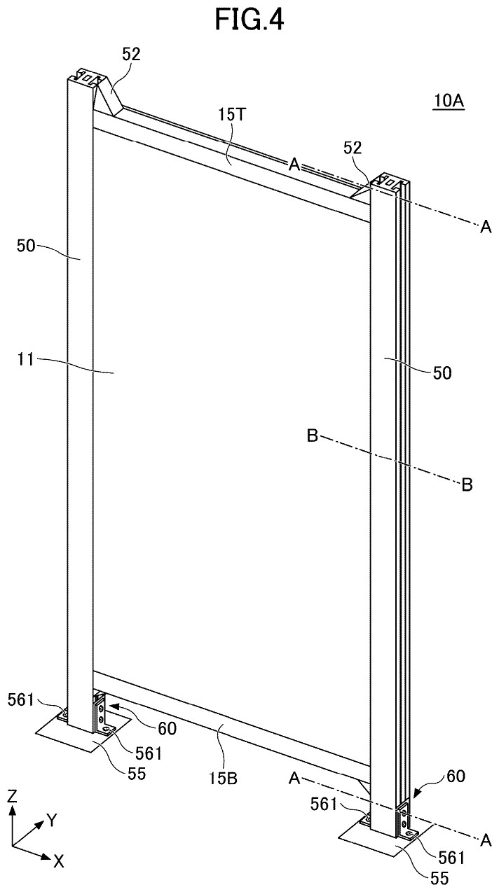

FIG. 4 is a schematic diagram illustrating an electromagnetic wave reflection device 10A according to a first embodiment. A height direction of the electromagnetic wave reflection device 10A is a Z direction, a width direction (or a connection direction) is an X direction, and a thickness direction is a Y direction. The electromagnetic wave reflection device 10A includes a reflection panel 11 configured to reflect radio waves in a desired band selected from the frequency band of 1 GHz to 170 GHz, a frame 50 configured to hold the reflection panel 11, and a leg 55 configured to support the frame 50. At least one of the frame 50 or the leg 55 includes an adjuster 52 and/or 60 configured to adjust the height of the reflection panel 11. The adjusters 52 and 60 are examples of the height adjustment mechanism H.

Two frames 50 hold two opposing sides along the height direction of the reflection panel 11. The “height direction” of the reflection panel 11 refers to the Z direction perpendicular to an X-Y plane serving as the installation surface, while the electromagnetic wave reflection device 10A is installed. In addition to the frames 50, a top frame 15T holding an upper end of the reflection panel 11 and a bottom frame 15B holding a lower end may be used. In this case, the frames 50, the top frame 15T, and the bottom frame 15B constitute a frame holding the entire periphery of the reflection panel 11.

The frame 50 may be referred to as a “side frame” in relation to the top frame 15T and the bottom frame 15B. As described with reference to FIG. 3, the frame 50 serving as the side frame has a cross-sectional configuration that maintains continuity of the reflection potential between the adjacent reflection panels 11. By providing the top frame 15T and the bottom frame 15B in addition to the frame 50, mechanical strength and safety of the reflection panel 11 during transport and assembly are ensured. The top frame 15T and the bottom frame 15B may have the same cross-sectional configuration as the frame 50.

The adjuster 52 is provided, for example, at a corner between the side frame 50 and the top frame 15T or at a corner between the frame 50 and the bottom frame 15B, to adjust the height position of the reflection panel 11. The adjuster 60 is provided, for example, at the leg 55 to adjust the height position of the reflection panel 11. The adjuster 60 provided at the leg 55 may include a fixing hole 561 configured to fix the adjuster 60 to the leg 55.

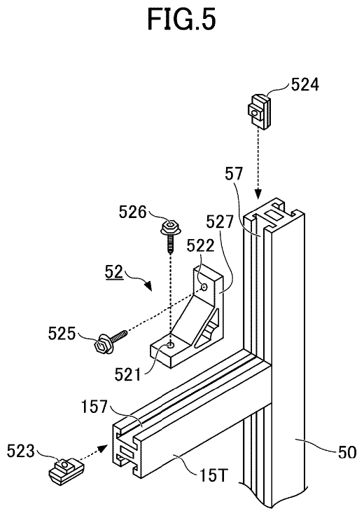

FIG. 5 is a schematic diagram of the adjuster 52. The adjuster 52 is provided at the corner of the frame 50 and the top frame 15T and includes a triangular bracket 527. Holes 521 and 522 are formed in the bracket 527. The adjuster 52 also includes a screw 525 inserted into the hole 522, a slide bracket 524 receiving the screw 525, a screw 526 inserted into the hole 521, and a slide bracket 523 having a screw hole receiving the screw 526. The slide bracket 524 is vertically slidable in a slit 57 formed in the frame 50. The slide bracket 523 is slidable in a slit 157 formed in the top frame 15T.

The reflection panel 11 is fixed to the top frame 15T by the screws 526 and the slide brackets 523. The height position of the reflection panel 11 fixed to the top frame 15T is adjusted by the screws 525 and the slide brackets 524. By using the adjuster 52 as a height adjustment mechanism, the height of the reflection surface of the electromagnetic wave reflection device 10A can be set to a desired height according to the conditions of the installation surface. When a plurality of electromagnetic wave reflection devices 10A are connected to form an electromagnetic wave reflection fence, the height positions between the plurality of reflection panels 11 are aligned even when the flatness of the installation surface of the electromagnetic wave reflection fence is poor.

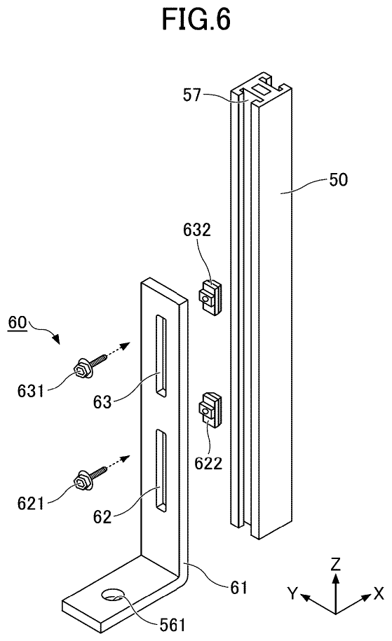

FIG. 6 is a schematic diagram of the adjuster 60. The adjuster 60 includes the leg 55 and an L-shaped bracket 61 attached to the lower end of the frame 50. The bracket 61 includes long holes 62 and 63 provided on an L-shaped surface in the height direction (Z direction), and the fixing hole 561 provided on an L-shaped surface in the horizontal direction (X direction). The adjuster 60 also includes a slide bracket 622 receiving a screw 621 inserted into the long hole 62, and a slide bracket 632 receiving a screw 631 inserted into the long hole 63. The slide brackets 622 and 632 are vertically slidable in the slit 57 formed in the frame 50.

The position of the lower end of the reflection panel 11 can be set to a predetermined height by making the slide brackets 622 and 632 slidable in the height direction (Z direction) and fixing them by the screws 621 and 631 at a desired height position. When a lower end position of the reflection panel 11 is determined, an upper end position of the reflection panel 11 is necessarily determined, so that the reflection panel 11 can be set to a desired height position. The number of pairs of the long holes and slide brackets slidable in the Z direction is not limited to two. Depending on the size, weight, etc. of the frame 50 and the reflection panel 11, the number of long holes may be one or three or more. The fixing hole 561 may be used to fix the bracket 61 to the leg 55 (see FIG. 4) by a screw, etc.

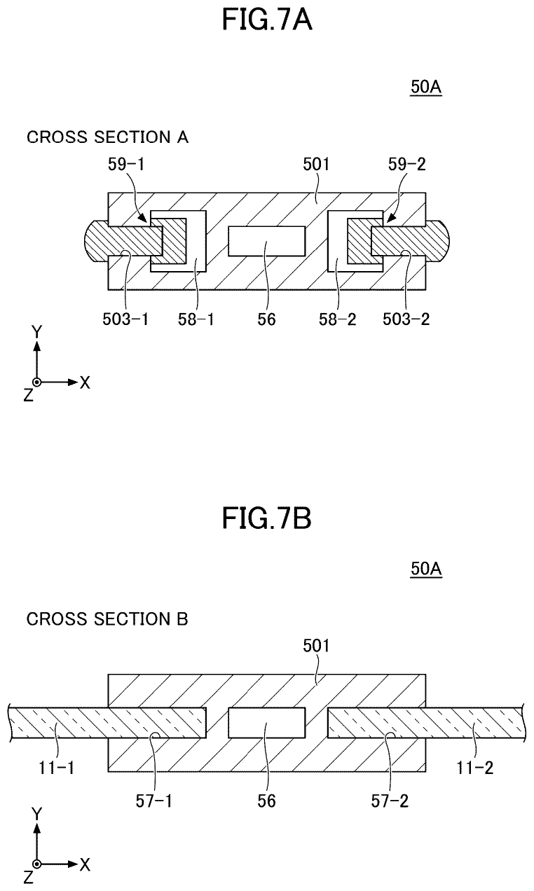

FIGS. 7A and 7B illustrate cross sections A and B taken at different height positions of a frame 50A. The cross section A of FIG. 7A is a horizontal cross section parallel to the X-Y plane when cut at a height position A of FIG. 4, and the cross section B of FIG. 7B is a horizontal cross section parallel to the X-Y plane when cut at a height position B of FIG. 4. The frame 50A as the side frame may have different cross sectional shapes at the height position A where the height adjustment mechanism H (adjusters 52, 60, etc.) is provided, and at the height position B where the reflection panel 11 is held. At the upper and lower ends of the frame 50A, as illustrated in FIG. 7A, the hollow 56 is formed in the center of the body 501. Also, on two opposing sides relative to the hollow 56, slits 503-1 and 503-2, and grooves 58-1 and 58-2 that respectively communicate with the slits 503-1 and 503-2, are formed. The grooves 58-1 and 58-2 accommodate adjusters 59-1 and 59-2, which function as the height adjustment mechanism H, slidably in the Z direction.

Additionally, as illustrated in FIG. 7B, in the cross section B configured to hold the reflection panels 11-1 and 11-2, the slits 57-1 and 57-2 configured to receive the side ends of the reflection panels 11-1 and 11-2 are formed on two opposing sides relative to the hollow 56. In FIG. 7B, the conductive films 115 (see FIG. 3) formed on the reflection panels 11-1 and 11-2 are omitted for the sake of illustration. In practice, the reflection panels 11-1 and 11-2 are provided with a conductive film that reflects electromagnetic waves in a predetermined frequency band and is electrically interconnected through the body 501 of the frame 50A.

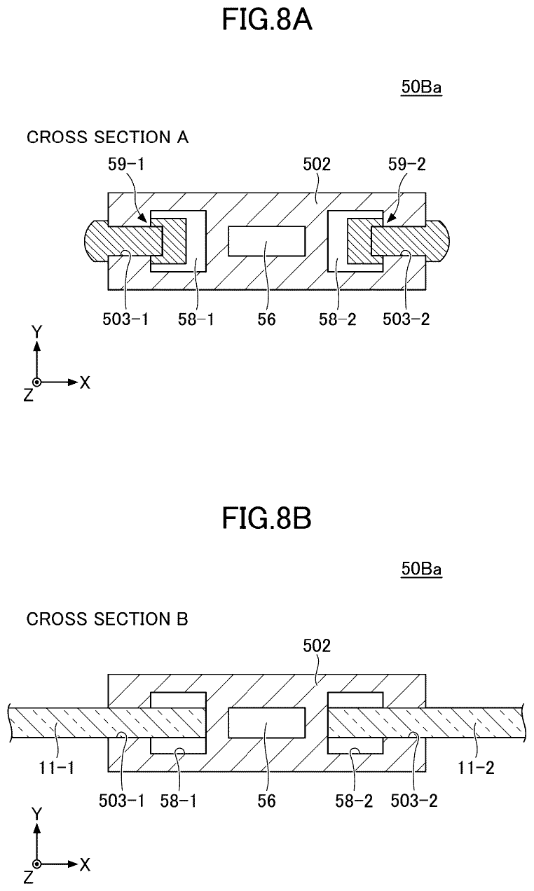

FIG. 8A illustrates cross section A and FIG. 8B illustrates cross section B taken at different height positions of a modified frame 50Ba. The cross sections A and B are horizontal cross sections parallel to the X-Y plane cut at height positions A and B of FIG. 4. A body 502 of the frame 50Ba has the same horizontal cross-sectional structure at the height position A, where the height adjustment mechanism H (such as adjusters 52, 60, etc.) is provided, and at the height position B, where the reflection panel 11 is held.

As illustrated in FIGS. 8A and 8B, the body 502 of the frame 50Ba includes slits 503-1 and 503-2 on two opposing sides relative to the hollow 56, and grooves 58-1 and 58-2 that respectively communicate with the slits 503-1 and 503-2. In FIG. 8A, the groove 58-1 accommodates the adjuster 59-1 and the groove 58-2 accommodates the adjuster 59-2. The adjusters 59-1 and 59-2, being the height adjustment mechanisms H, are arranged slidably in the Z direction. In FIG. 8B, the grooves 58-1 and 58-2 accommodate the side ends of the reflection panels 11-1 and 11-2 inserted through the slits 503-1 and 503-2. The frame 50Ba has the same cross-sectional shape in the Z direction, making it easier to mold and extrude, thus reducing manufacturing costs. Further, since the volumes of the grooves 58-1 and 58-2 are larger than those of the slits 57-1 and 57-2 in FIG. 7A, the frame 50B can be further reduced in weight.

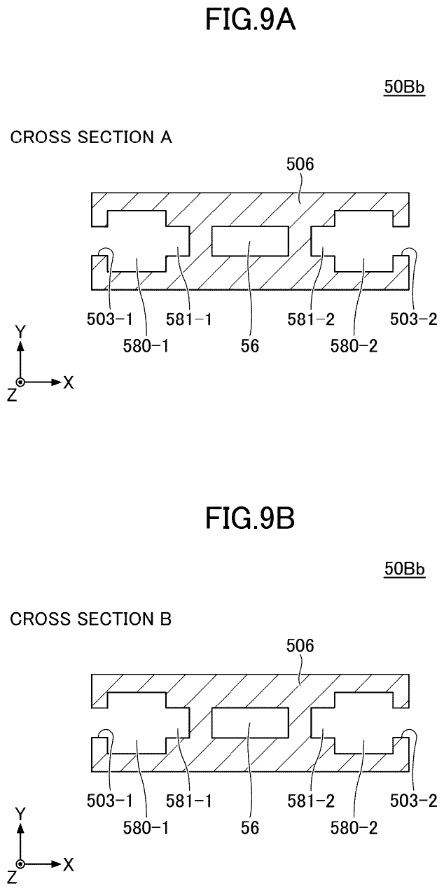

FIGS. 9A and 9B are views illustrating cross section A and cross section B of a frame 50Bb, which is another modified example. Like the frame 50Ba, the frame 50Bb has the same horizontal cross-sectional structure for the cross sections A and B taken at different height positions. A hollow 56 is provided in the center of a body 506 of the frame 50Bb. To the sides of the hollow 56, slits 503-1 and 503-2 and grooves 580-1 and 580-2 that communicate with the slits 503-1 and 503-2 are provided. The grooves 580-1 and 580-2 include recesses 581-1 and 581-2, respectively, toward the hollow 56. The grooves 580-1 and 580-2, including the recesses 581-1 and 581-2, respectively, do not communicate with the hollow 56. In this configuration, the frame structure is uniform, and the mold fabrication and extrusion are easy. Further, at the position B in the height direction, the ends of the reflection panels 11 inserted from the slits 503-1 and 503-2 can be received by the recesses 581-1 and 581-2, so that the holding state of the reflection panels 11 is stabilized. The grooves 580-1 and 580-2 accommodating the reflection panels 11-1 and 11-2 can also be used for fixing the reflection panels 11 by inserting components such as bolts and nuts.

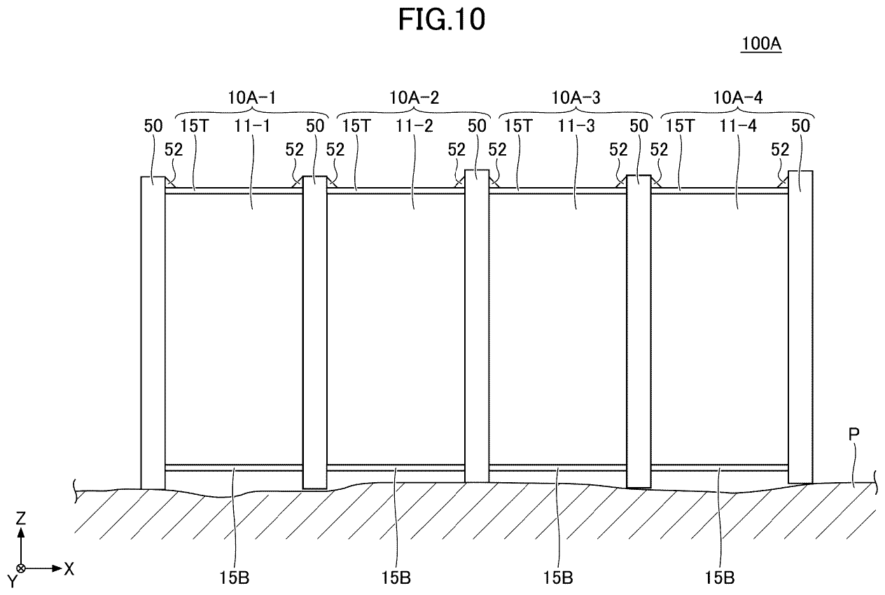

FIG. 10 is a schematic diagram illustrating an electromagnetic wave reflection fence 100A after assembly. In this example, four electromagnetic wave reflection devices 10A-1, 10A-2, 10A-3, and 10A-4 are connected in the X direction. Although the electromagnetic wave reflection fence 100A is installed on an installation surface P having poor flatness, the height positions of the reflection panels 11-1, 11-2, 11-3, and 11-4 are aligned by the adjuster 52. Needless to say, the adjuster 60 may be used in place of the adjuster 52 or in conjunction with the adjuster 52. The alignment of the height positions of the plurality of reflection panels 11-1, 11-2, 11-3, and 11-4 allows the electromagnetic wave reflection fence 100A to maintain its reflection characteristics and to function as a safety fence of a constant height.

### Second Embodiment

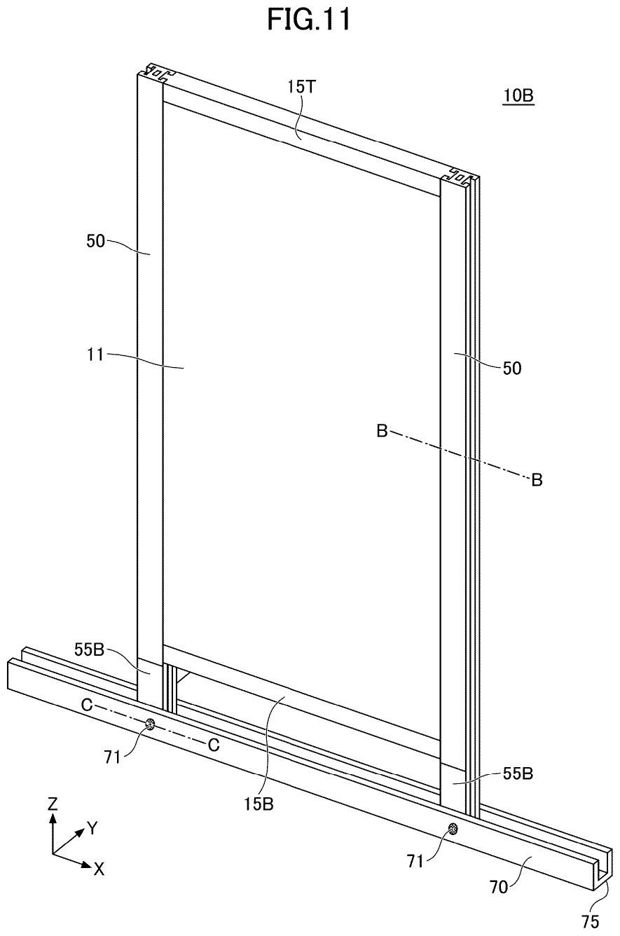

FIG. 11 is a schematic diagram illustrating an electromagnetic wave reflection device 10B of a second embodiment. The electromagnetic wave reflection device 10B includes a reflection panel 11 configured to reflect radio waves in a desired band selected from a frequency band of 1 GHz to 170 GHz, a frame 50 for holding the reflection panel 11, and a leg 55B for supporting the frame 50. In the electromagnetic wave reflection device 10B, a rail 70 is provided on the leg 55B as a height adjustment mechanism for adjusting a relative height of the reflection panel 11 with respect to an installation surface. As long as the rail 70 can hold the leg 55B of the electromagnetic wave reflection device 10B, there is no particular restriction on its shape or configuration. As an example, a U-shaped joiner is used as the rail 70.

Side ends of the reflection panel 11 along the height direction are held by the frames 50, which are the side frames. The horizontal cross section taken along B-B line may be, for example, the same as the cross section B of the frame 50A as illustrated in FIG. 7B. An upper end of the reflection panel 11 may be held at a top frame 15T and a lower end may be held at a bottom frame 15B.

The leg 55B supporting the frame 50 is slidably engaged with the rail 70 and fixed at a predetermined position by a screw 71. Since the rail 70 includes a flat bottom surface 75, the electromagnetic wave reflection device 10B can be stably installed even when the electromagnetic wave reflection device 10B is placed on an installation surface with poor flatness. The height position of the reflection panel 11 is fixed with respect to the rail 70, but the height position relative to the unevenness of the installation surface is adjusted by the rail 70. In this sense, the rail 70 also functions as a height adjustment mechanism.

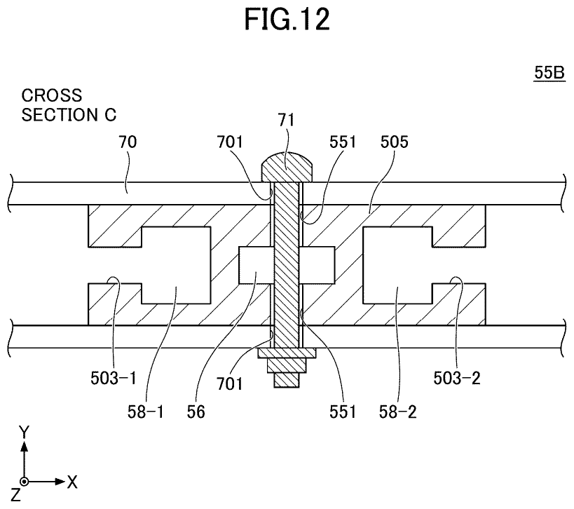

FIG. 12 is a view illustrating cross section C of FIG. 11. The cross section C is a horizontal cross section of the leg 55B when cut in a plane parallel to the X-Y plane at a C-C position. The leg 55B includes a body 505. The leg 55B may be made of any material since it does not contribute to the electrical connection of the reflection panel 11. The body 505 is provided with a hollow 56, and includes grooves 58-1 and 58-2 that respectively communicate with slits 503-1 and 503-2 and are arranged on two opposing sides relative to the hollow 56.

The body 505 of the leg 55B also includes a hole 551 that communicates with the hollow 56 in the Y direction. The rail 70 includes holes 701 formed at predetermined positions, and the electromagnetic wave reflection device 10B can be fixed to the rail 70 at a predetermined height by fixing the hole 551 of the leg 55B to the holes 701 of the rail 70 with a screw 71. The body of the leg 55B and the frame 50 may be integrally formed. In this case, the leg 55B is made of the same material as the frame 50, and the hole 551 that communicates with the hollow 56 is provided at a predetermined position of the leg 55B. This configuration is advantageous in terms of manufacturing cost.

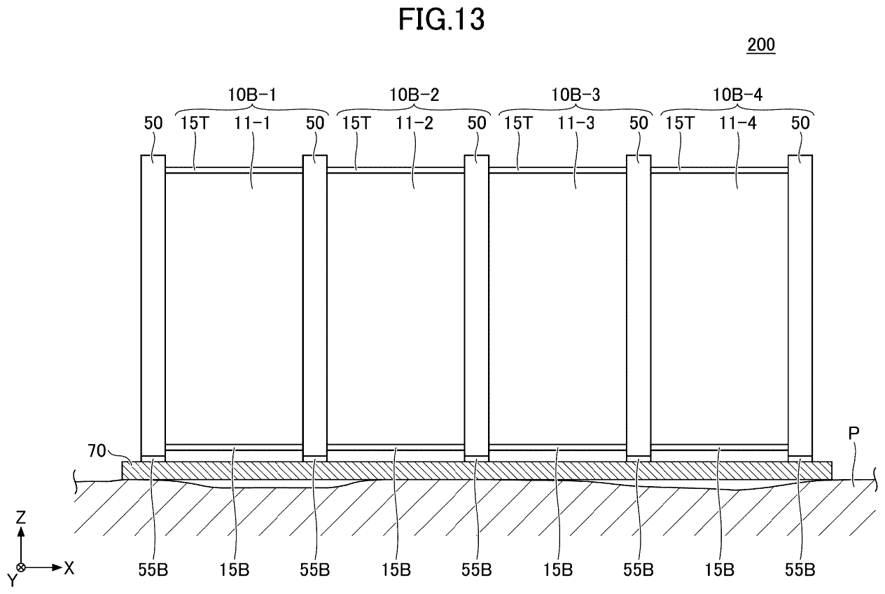

FIG. 13 is a schematic diagram illustrating an electromagnetic wave reflection fence 200 after assembly. In this example, four electromagnetic wave reflection devices 10B-1, 10B-2, 10B-3, and 10B-4 are connected in the X direction. Although the electromagnetic wave reflection fence 200 is installed on an installation surface P having poor flatness, the legs 55B of the electromagnetic wave reflection devices 10B-1, 10B-2, 10B-3, and 10B-4 are fixed to the flat rail 70, and the height positions of the reflection panels 11-1, 11-2, 11-3, and 11-4 are aligned. When a gap is formed between the installation surface P and the rail 70, a spacer or a filler such as urethane foam may be inserted to fill the gap. This stabilizes the rail 70 and improves the stability of the installation of the electromagnetic wave reflection fence 200.

### Third Embodiment

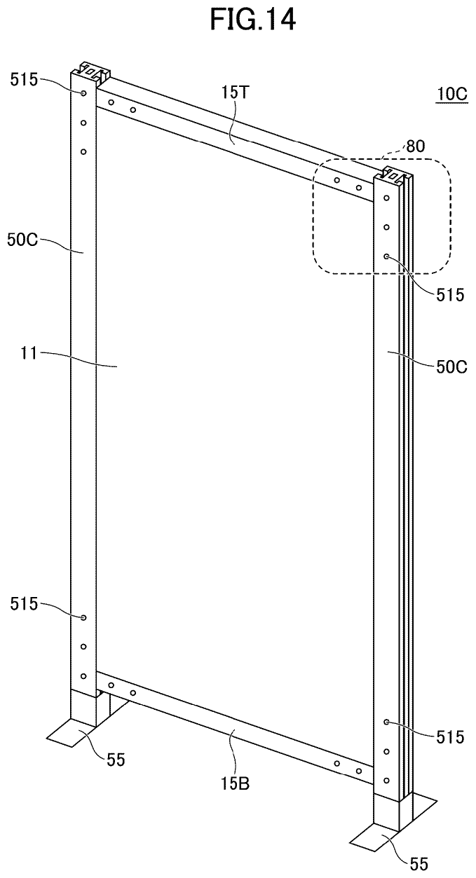

FIG. 14 is a schematic diagram illustrating an electromagnetic wave reflection device 10C of a third embodiment. In the third embodiment, a height adjustment mechanism 80 is provided at a corner between a frame 50C and a top frame 15T. The electromagnetic wave reflection device 10C includes a reflection panel 11 configured to reflect radio waves in a desired band selected from a frequency band of 1 GHz to 170 GHz, the frame 50C for holding the reflection panel 11, and a leg 55 for supporting the frame 50C. The lower end of the reflection panel 11 may be held in a bottom frame 15B.

Alternatively, a height adjustment mechanism 80 may be provided at a corner of the frame 50C and the bottom frame 15B, along with a corner of the frame 50C and the top frame 15T, instead of being provided at the corner of the frame 50C and the top frame 15T. A hole 515 is formed in the upper end of the frame 50C and the top frame 15T, and/or in the lower end of the frame 50C and the bottom frame 15B. The hole 515 embodies the height adjustment mechanism 80 together with a T-shaped adjuster 81 to be described in the following.

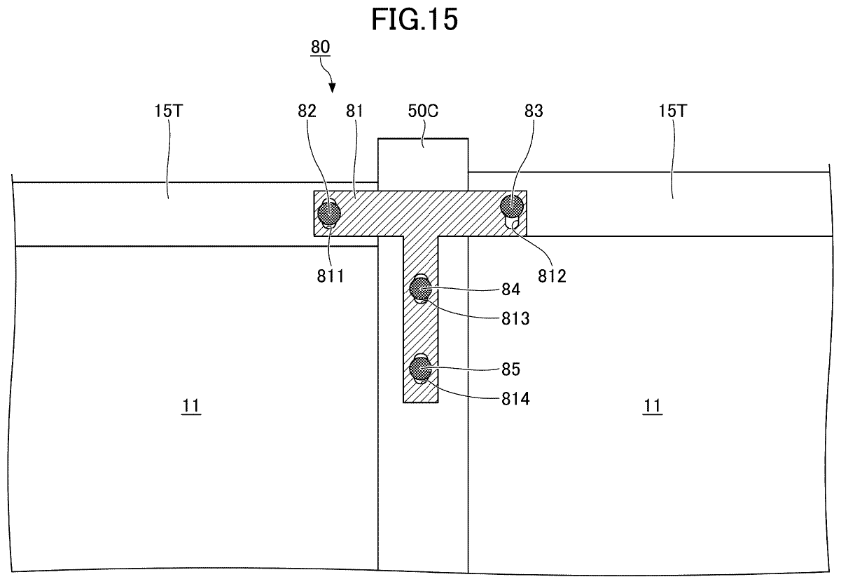

FIG. 15 is a schematic diagram illustrating the height adjustment mechanism 80. The height adjustment mechanism 80 includes the T-shaped adjuster 81. Long holes 811, 812, 813, and 814 are formed in the T-shaped adjuster 81. In the illustrated example, the T-shaped adjuster 81 is attached to the upper end of the frame 50C and the top frames 15T on both sides of the frame 50C by screws 82, 83, 84, and 85. The T-shaped adjuster 81 is fixed so that the positions of the long holes 811, 812, 813, and 814 correspond to the positions of the holes 515 (see FIG. 14) formed in the frame 50C and the top frames 15T. The inner configuration of the frame 50C holding the reflection panel 11 may be the same as the horizontal cross section of the frame 50 as illustrated in FIG. 3. A gap between the frame 50C and the top frame 15T may be filled by inserting a spacer or a filler such as urethane foam.

When connecting a plurality of electromagnetic wave reflection devices 10C to install an electromagnetic wave reflection fence on an installation surface with poor flatness, the reflection panel 11 is held by using the long holes 811, 812, 813, and 814 so that the height positions of adjacent reflection panels 11 are aligned as much as possible regardless of the difference in height positions of the legs 55. Thus, the electromagnetic wave reflection fence can be easily assembled and installed while maintaining the reflection characteristics of the electromagnetic wave reflection fence according to the conditions of the installation surface.

### <Application to Process Line>

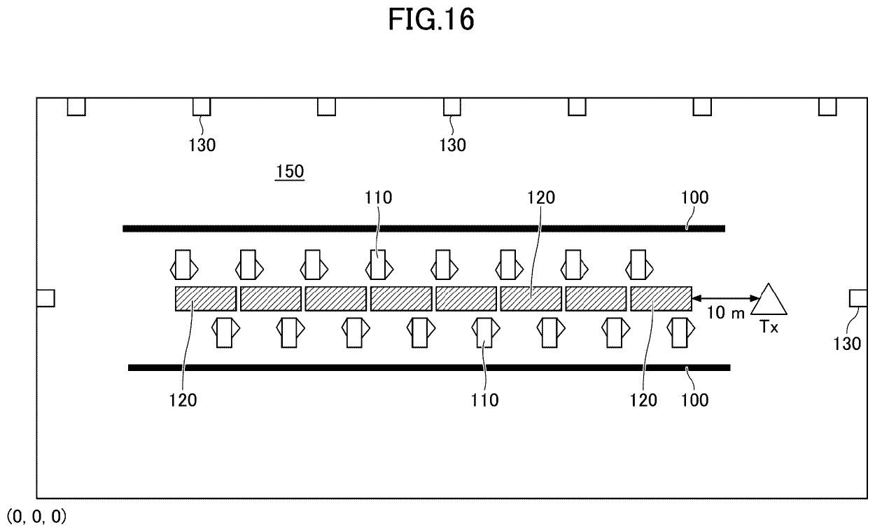

FIG. 16 is a schematic diagram of a process line 150 to which an electromagnetic wave reflection fence 100 is applied. Coordinates of the lower left corner are (0, 0, 0). In the process line 150 for assembling a vehicle, an electric appliance, a machine, etc., a plurality of production devices 110 such as a robot arm are arranged in the process line 150, and assembly parts 120 move between the production devices 110. The production device 110 is provided with a communicator and transmits and receives radio signals to and from a transmission station Tx installed near the process line 150. The transmission station Tx and the production device 110 transmit and receive signals at a desired frequency selected from, for example, a frequency band within a range of 24 GHZ to 32 GHZ.

Within a facility where the process line 150 is provided, there are structures such as columns 130, shelves, and racks. Radio signals transmitted from the transmission station Tx are reflected or scattered by the structures such as the columns 130 and production devices 110. As the distance between the transmission station Tx and a transmission antenna increases, reception quality deteriorates. As illustrated in FIG. 16, the communication environment of the process line 150 is improved by providing the electromagnetic wave reflection fences 100 along the process line 150.

In order to stably deliver signals to the production devices 110 in the process line 150, it is desirable that the heights of the electromagnetic wave reflection fence 100 are aligned to a certain extent. When the height of the electromagnetic wave reflection fence 100 varies from place to place, levels of the reflection characteristics inside the process line 150 may vary. The reflection characteristics of the electromagnetic wave reflection fence 100 are confirmed by simulation.

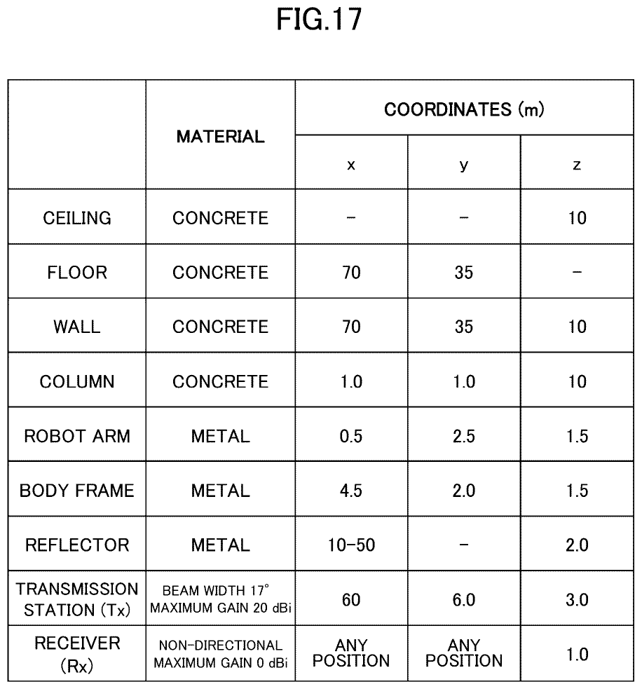

FIG. 17 is a table that summarizes specifications of the process line 150 used in the simulation. The process line 150 is provided along a longitudinal direction (X direction) on a part of a floor sized 70 m×35 m. The floor, walls and ceiling are made of concrete, and the height of the ceiling is 10 m. There are columns 130 each sized 1 m×1 m×10 m in the facility. There is a metal robot arm and a metal body frame in the process line 150.

The electromagnetic wave reflection fence 100 is used as a reflector. The electromagnetic wave reflection fence 100, on one side, is formed by connecting 40 electromagnetic wave reflection devices 10 including the reflection panel 11 having a width of 1 m and a height of 2 m. The electromagnetic wave reflection fence is provided on both sides of the process line 150. The length of the reflector in the X direction is 40 m, and a transmission station Tx is installed at a position 10 m away from the end of the reflector. A transmitting antenna used in the transmission station Tx is a directional antenna having a beam width of 17°, and its maximum gain is 20 dBi. The height position of the transmitting antenna is 3.0 m. A receiver Rx may take any coordinate position on an X-Y plane to measure distribution of the electromagnetic field strength within the floor. The receiving antenna is a non-directional antenna with a maximum gain of 0 dBi and a height position of 1.0 m.

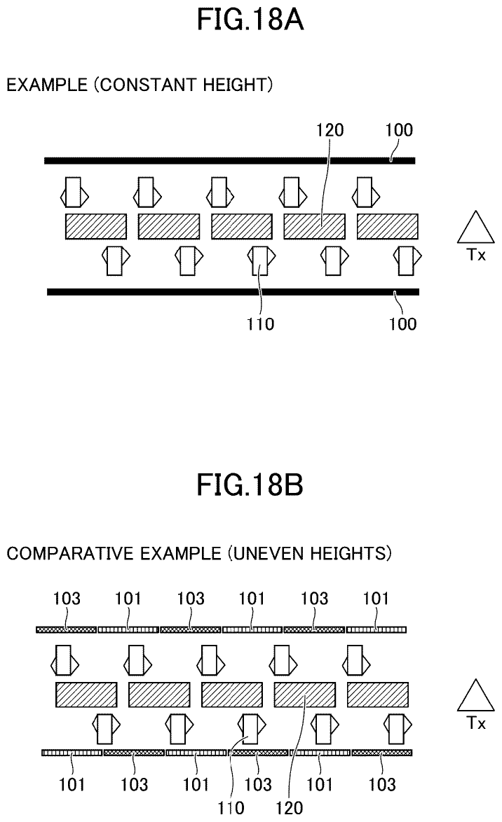

FIG. 18A illustrates an example model and FIG. 18B illustrates a comparative example model, that use a part of the model in FIG. 16. Throughout the example and comparative example, the size (width×height) of the reflection panel is 1 m×2 m. As illustrated in FIG. 18A, the height of the electromagnetic wave reflection fence 100, that is the height from the floor to the upper end of the reflection panel 11 including the legs 55, of the example is constant at 2.4 m. In contrast, as illustrated in FIG. 18B, the height of the reflector of the comparative example is uneven by alternately arranging electromagnetic wave reflection devices 101 and 103 having different heights.

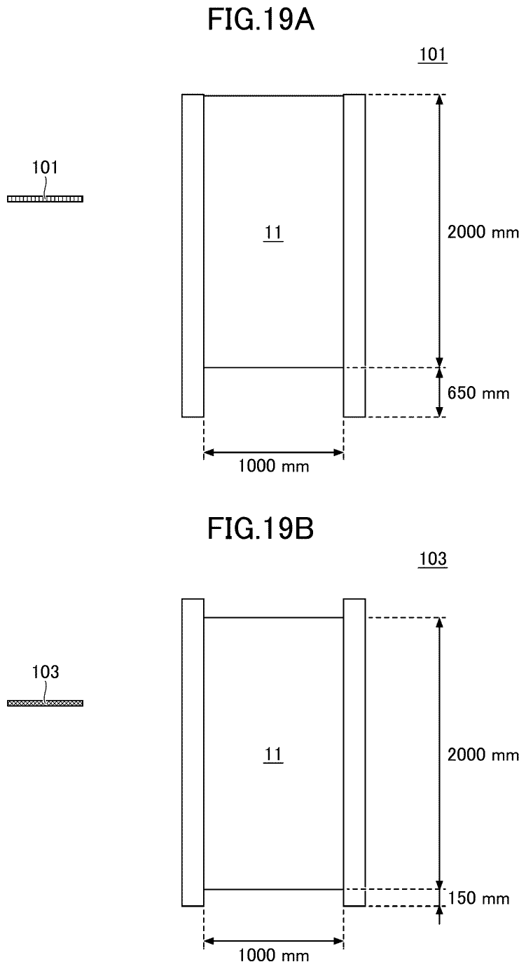

FIGS. 19A and 19B illustrate models of the electromagnetic wave reflection device of different heights used in the comparative example. The size of the reflection panel 11 used in the electromagnetic wave reflection device 101 is 1,000 mm×2,000 mm, and the height of the lower end of the reflection panel 11 is 650 mm. The size of the reflection panel 11 used in the electromagnetic wave reflection device 103 is 1,000 mm×2,000 mm, and the height of the lower end of the reflection panel 11 is 150 mm. There is a height difference of 50 cm between the electromagnetic wave reflection devices 101 and 103. Although a height difference of 1 cm to 5 cm is common in actual installation surfaces such as factories, a height difference of 50 cm is provided to make the difference of electromagnetic field intensity distribution visible.

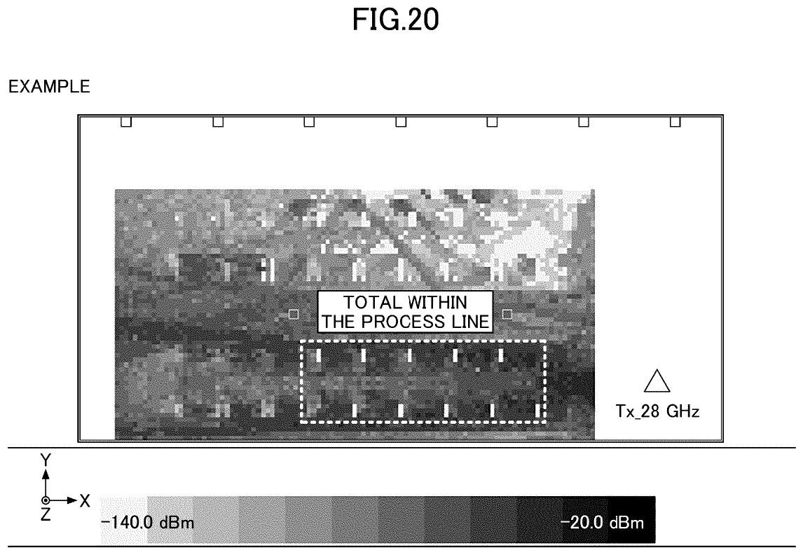

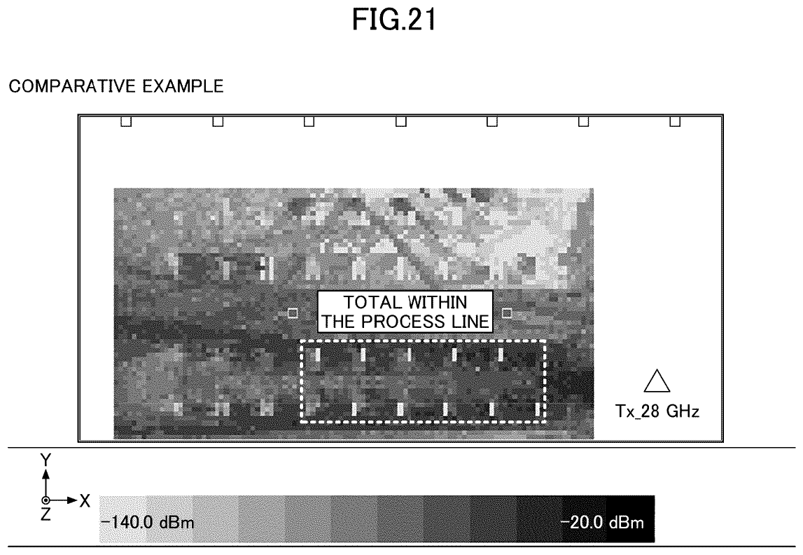

FIG. 20 illustrates a result of an electromagnetic field simulation of the example. FIG. 21 illustrates a result of an electromagnetic field simulation of the comparative example. In the example of FIG. 20, the electromagnetic wave reflection fence 100 having a total area of 60 m² (30 reflection panels 11, each sized 1 m×2 m, connected together) is arranged on both sides (30 panels per side) of the process line of the specifications as described in FIG. 17. Then, for an area within the process line 150, distribution of the intensity of the received electromagnetic wave transmitted at a frequency of 28.3 GHz is obtained. Based on the result of FIG. 20, the total received intensity in the process line 150 is calculated to be −58,454 dBm.

In the comparative example of FIG. 21, an electromagnetic wave reflection fence having a total area of 60 m² (30 reflection panels 11, each sized 1 m×2 m, connected together) with a partial height difference of 50 cm is placed on both sides (30 panels per side) of the process line of the specifications as described in FIG. 17. Then, for an area within the process line 150, distribution of the intensity of the received electromagnetic wave transmitted at a frequency of 28.3 GHZ is obtained. Based on a result of FIG. 21, the total received intensity in the process line 150 is calculated to be −58,795 dBm. It is confirmed that the received intensity is reduced compared with the case of using the electromagnetic wave reflection fence 100 of a constant height in FIG. 20.

Even when the height difference of the installation surface P is within 5 to 10 cm, it is considered that the total received intensity in the process line 150 is affected when the process line 150 becomes long. In the electromagnetic wave reflection device of the embodiment, the height position of the reflection panel 11 can be adjusted in spite of the unevenness of the installation surface P, so that the height of the reflection panel 11 can be brought close to a constant height. When the electromagnetic wave reflection fence 100, 100A, or 200 is also used as a safety protection fence, a safety level is made uniform by aligning the height position of the safety protection fence.

The electromagnetic wave reflection devices 10, 10A, 10B, and 10C and the electromagnetic wave reflection fences 100, 100A, and 200 of the embodiments are easy to carry in, assemble, and install in the field. The individual electromagnetic wave reflection devices may be conveyed with the reflection panel 11, the frame 50 as the side frame, the top frame 15T, the bottom frame 15B, and the leg 55 all separately, or with the top frame 15 and the bottom frame 15B attached to the upper and lower ends of the reflection panel 11. Alternatively, the electromagnetic wave reflection device may be conveyed with the frame 50 attached to one side end thereof. In these cases, the remainder may be assembled at the installation site. The height position of the reflection panel 11 can also be easily adjusted at the site according to the condition of the installation surface.

The installation method of the electromagnetic wave reflection device includes: (a) assembling the electromagnetic wave reflection device by holding, by the frame, the reflection panel 11 configured to reflect radio waves of the desired band selected from the frequency band of 1 GHz to 170 GHz; (b) installing the electromagnetic wave reflection device on the installation surface; and (c) adjusting the height position of the reflection panel 11 relative to the installation surface by the height adjustment mechanism provided in the electromagnetic wave reflection device.

The installation method of the electromagnetic wave reflection fence includes: (a) assembling the electromagnetic wave reflection fence configured to reflect radio waves of the desired band selected from the frequency band of 1 GHz to 170 GHz, by connecting the first electromagnetic wave reflection device including the first reflection panel and the second electromagnetic wave reflection device including a second reflection panel by the frame; (b) installing the electromagnetic wave reflection fence on the installation surface; and (c) adjusting height positions of the first reflection panel and the second reflection panel relative to the installation surface by using the height adjustment mechanism provided in the first electromagnetic wave reflection device or the second electromagnetic wave reflection device. According to the installation methods of the electromagnetic wave reflection device and the electromagnetic wave reflection fence, the height can be easily adjusted according to the conditions of the installation surface even when the flatness of the installation surface is poor.

Although the present disclosure has been described based on specific examples, the present disclosure is not limited to the above-mentioned configuration examples. The hollow 56 provided in the frame 50 (or any of 50 A to 50 C) is not always required, and the hollow need not be provided when a lightweight conductive material is used. When the rail 70 is used as a height adjustment mechanism to keep the height of the reflection panel constant, a hat joiner with a projecting center may be used for the rail instead of a U-shaped joiner. In this case, the leg 55B may have a horizontal cross-sectional shape that fits on both sides of the projecting center of the rail 70. Instead of continuous height adjustment using a long hole, a stepwise height adjustment mechanism may be used.

The size (width×height) of the reflection panel 11 of the electromagnetic wave reflection device 10 (or any of 10A to 10C) is not limited to 1 m×2 m, but is appropriately selected from a range of 30 cm×30 cm to 3 m×3 m. As the size of the reflection panel 11 increases, the effect of height variation is likely to appear, and the height adjustment of the embodiments becomes more effective. When a plurality of reflection panels 11 are connected to be used as an electromagnetic wave reflection fence, the frame 50 (or any of 50A to 50C) is used to align the upper ends of the reflection panels while maintaining continuity of the reflection potential between adjacent reflection panels 11. The electromagnetic wave reflection device and the electromagnetic wave reflection fence of the embodiment are effectively used not only for process lines, but also for indoor and outdoor event facilities, such as, where many exhibits are displayed, a large number of people tend to line up, and in offices where many electronic devices are used.

What is claimed is:

1. An electromagnetic wave reflection device, comprising:
a reflection panel configured to reflect radio waves of a desired band selected from a frequency band of 1 GHz to 170 GHz;
a frame configured to hold the reflection panel;
a leg configured to support the frame; and
a height adjustment mechanism configured to adjust a height of the reflection panel, the height adjustment mechanism being provided on at least one of the frame or the leg.

2. The electromagnetic wave reflection device according to claim 1, wherein
the frame includes,
a side frame configured to hold a side end of the reflection panel,
a top frame configured to hold an upper end of the reflection panel, and
a bottom frame configured to hold a lower end of the reflection panel, and
the height adjustment mechanism is provided, at a corner between the side frame and the top frame, or at a corner between the side frame and the bottom frame, to adjust a height position of the reflection panel.

3. The electromagnetic wave reflection device according to claim 1, wherein
the frame includes a side frame configured to hold a side end of the reflection panel that is along a height direction of the reflection panel, and
the height adjustment mechanism is provided between the leg and the side frame, to adjust a height position of the reflection panel.

4. The electromagnetic wave reflection device according to claim 1, wherein
the height adjustment mechanism is a rail that is engaged with the leg, and
the leg is slidably engaged with the rail and fixed at a predetermined position along a longitudinal direction of the rail.

5. The electromagnetic wave reflection device according to claim 1, wherein
the frame includes a side frame configured to hold a side end of the reflection panel that is along a height direction of the reflection panel, and
the side frame includes
a slit that receives the side end of the reflection panel, and
a hollow that does not communicate with the slit.

6. The electromagnetic wave reflection device according to claim 2, wherein
the side frame includes
a slit that receives the side end of the reflection panel, and
a hollow that does not communicate with the slit.

7. The electromagnetic wave reflection device according to claim 1, wherein
the height adjustment mechanism is provided on the frame, and
a part of the frame that holds the reflection panel has a same cross-sectional structure as a part of the frame where the height adjustment mechanism is provided.

8. The electromagnetic wave reflection device according to claim 1, wherein
the height adjustment mechanism is provided on the frame, and
a part of the frame that holds the reflection panel has a different cross-sectional structure than a part of the frame where the height adjustment mechanism is provided.

9. An electromagnetic wave reflection fence, comprising:
a plurality of electromagnetic wave reflection devices each being the electromagnetic wave reflection device of claim 1, wherein
the electromagnetic wave reflection devices are connected in a width direction of the reflection panel, and
height positions of a plurality of the reflection panels are aligned by the height adjustment mechanism.

10. An installation method of an electromagnetic wave reflection device, the installation method comprising:
assembling the electromagnetic wave reflection device by holding, by a frame, a reflection panel configured to reflect radio waves of a desired band selected from a frequency band of 1 GHz to 170 GHz;
installing the electromagnetic wave reflection device on an installation surface; and
adjusting a height position of the reflection panel relative to the installation surface by a height adjustment mechanism provided in the electromagnetic wave reflection device.

11. An installation method of an electromagnetic wave reflection fence, the installation method comprising:
assembling the electromagnetic wave reflection fence configured to reflect radio waves of a desired band selected from a frequency band of 1 GHz to 170 GHz, by connecting a first electromagnetic wave reflection device including a first reflection panel and a second electromagnetic wave reflection device including a second reflection panel by a frame;
installing the electromagnetic wave reflection fence on an installation surface; and
adjusting height positions of the first reflection panel and the second reflection panel relative to the installation surface by using a height adjustment mechanism provided in the first electromagnetic wave reflection device or the second electromagnetic wave reflection device.
